(19) United States
(12) Patent Application Publication
(10) Pub. No.: US 2002/0002771 A1
(43) Pub. Date: Jan. 10, 2002

(54) Method for making a planar inductor/transformer in a laminated printed circuit board

(75) Inventors: Wen-Yen Lin, Taoyuan Hsien (TW); Chin-Chi Chang, Taoyuan Hsien (TW)

Correspondence Address: Jackson Walker L.L.P., Suite 2100, 112 E. Pecan, San Antonio, TX, 78205, US

(73) Assignee: Compeq Manufacturing Company Limited

(21) Appl. No.: 09/942,235

(22) Filed: Aug. 29, 2001

Related U.S. Application Data
(62) Division of application No. 09/507,621, filed on Feb. 21, 2000.

(51) Int. Cl. H01F 7/06; H05K 3/02

(52) U.S. Cl. 29/602.1; 29/607; 29/847

(57) ABSTRACT

A method for making a planar inductor is disclosed. The inductor is made by using a core with high magnetic flux. Outside the substrate, a layer of insulator and conductive foil is securely mounted. Thereafter, copper traces are formed on the insulator. Before the copper traces are formed, holes are defined and metalized to provide electrical connection between conductive foils on opposite sides of the core, which forms a planar inductance. Furthermore, if the copper traces are breaking up in a predetermined location, the planar inductance becomes a transformer.

### CROSS REFERENCE

This is a divisional application of the parent application Ser. No. 09/507,621, filed on Feb. 21, 2000 by the same applicants, Wen-Yen LIN and Chin-Chi CHANG.

### BACKGROUND OF THE INVENTION

1. Field of the Invention

The present invention relates to a method for making an inductor/transformer, and more particularly to a method for making a planar inductor/transformer in a laminated printed circuit board (PCB).

2. Description of Related Art

Due to the demand of both high-speed and miniaturized electronics, there has been an increasing concern about the size of the circuit board as well as its electric characteristics. Employment of conventional discrete passive components means that extra space needed and the electric current loop formed will inevitably introduce parasitic resistance, capacitance and inductance into the system. Unfortunately, under high frequency, the parasitic inductance is the cause for the electromagnetic radiation and impedance variations. Those who are skilled in the art will understand how serious this situation will affect the function of circuitry.

To further address this issue, embedding these passive components into the PCB is hence introduced. Of all these three major passive components resistor, capacitor and inductor, the first two attracted most attention at the beginning. Materials with high dielectric constants are being developed to offer high capacitance density. Thin films made of nickel are laminated between copper foils and dielectric layers as resistors. For embedded inductors, there has been a developing interest in recent years. The first proposed implementation is in planar configuration comprising helical metal runners on a printed circuit board. More than one layer may be needed if a higher inductance value is desired. Connection of these traces at different layers is achieved through drilled holes with their inside walls plated with conductors. One problem remains in the planar inductors, which is the relatively low allowance of current density. Conventional art provides that by altering the widths of these metal runners, the maximum current density can be enhanced. This approach, nevertheless, proves to be inefficient due to the “Skin Effect” accompanying any current loop. The magnetic field induced by passing current tends to push itself outwards. For a long straight wire, electric current will only travel along the surface within finite depth which is inversely proportional to frequency. For a wired coil like a solenoid, current will be pushed further to the outmost edge from the axis. In the planar implementation, the effective area for current flow is the thickness of metal runners multiplied by the skin depth at a certain frequency. No matter how wide the trace is, current only travels along the outermost boundaries. The implementation that is suggested in U.S. Pat. No. 5,461,353 (hereinafter '353) issued to Eberhardt and having the title of “Printed Circuit Board Inductor” did solve the problem of low current density. This kind of arrangement still has its drawbacks, such as:

The inductance value may be too low for most applications given a fixed footprint.

One can, of course, increase the number of turns of the solenoid as well as the wiring density to increase the inductance value. The downside, however, is a large footprint which is opposed to the original idea of implementing embedded inductors at the first place.

According to the above description, it is noted that improvements to the existing inductor are necessary so as to solve the above mentioned problems.

To overcome the shortcomings, the present invention tends to provide an improved method to produce a planar inductor to mitigate and obviate the aforementioned problems.

### SUMMARY OF THE INVENTION

The main objective of the invention is to provide an improved method to produce a planar inductor/transformer in a laminated printed circuit board.

Another objective of the invention is to produce an inductor having increased magnetic flux capacity when compared with a conventional coil.

Still another objective of the invention is to use a core made from a material selected from the group consisting of iron, tungsten, manganese, cobalt and nickel instead of a printed circuit board to increase the magnetic flux.

In order to accomplish the above mentioned objective, the method in accordance with present invention comprises the steps of:

a process of producing a core with high magnetic flux, which includes the steps of adding dry foils on opposite sides of the core and etching the dry foils to form traces on the surface of the core;

a process of pressing epoxy resin and copper foil on the traces so as to press the resin into first holes defined through the opposite sides of the core;

a process of metalizing second holes defined to correspond to the first holes for electrical connection between the copper foils on the opposite sides on the core; and

a process of forming copper traces on dry foils added on top of the copper foils, which uses a photographic technique to transform patterns on the dry foils onto the copper foil and then excess copper is removed from the dry foil so as to form copper traces on the epoxy resin.

Still, another objective of the method in accordance with the present invention is to provide a transformer, which comprises the steps of:

a process of producing a core with high magnetic flux, which includes the steps of adding dry foils on opposite sides of the core and etching the dry foils to form traces on the surface of the core;

a process of pressing epoxy resin and copper foil on the traces so as to press the resin into first holes defined through the opposite sides of the core;

a process of metalizing second holes defined to correspond to the first holes for electrical connection between the copper foils on the opposite sides on the core;

a process of forming copper traces on dry foils added on top of the copper foils, which uses a photographic technique to transform patterns on the dry foils onto the copper foil and then excess copper is removed from the dry foil so as to form copper traces on the epoxy resin; and

breaking the copper traces on the epoxy resin and extending two ends from the cut copper traces for further connection.

Other objects, advantages and novel features of the invention will become more apparent from the following detailed description when taken in conjunction with the accompanying drawings.

### BRIEF DESCRIPTION OF THE DRAWINGS

FIG. 1 is a flow chart showing the process necessary for making an inductance;

FIG. 2 is a side view in cross section showing the internal structure of a core of the inductance produced by the flow chart shown in FIG. 1;

FIG. 3A˜FIG. 3C are schematic views showing the process of forming copper pattern on the core;

FIG. 4A, FIG. 4B are schematic views explaining the process of pressing;

FIG. 5A˜FIG. 5C are schematic views showing the process of metalizing holes defined through the core, the epoxy resin and copper foils for electrical connection between the copper foils on the opposite sides on the pressed structure;

FIG. 6A˜FIG. 6C are schematic views showing the process of forming copper traces;

FIG. 7 is a schematic view showing the inductance produced by the method of the invention;

FIG. 8A˜FIG. 8D are a schematic views showing an alternate process of pressing and metalizing the holes; and

FIG. 9A˜FIG. 9C are schematic views showing the process of forming copper traces.

### DETAILED DESCRIPTION OF THE PREFERRED EMBODIMENT

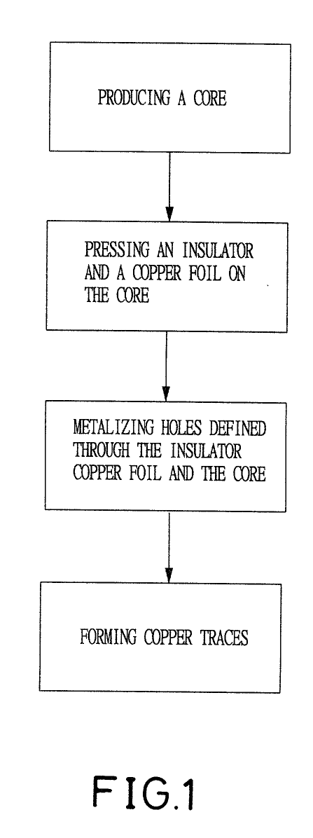

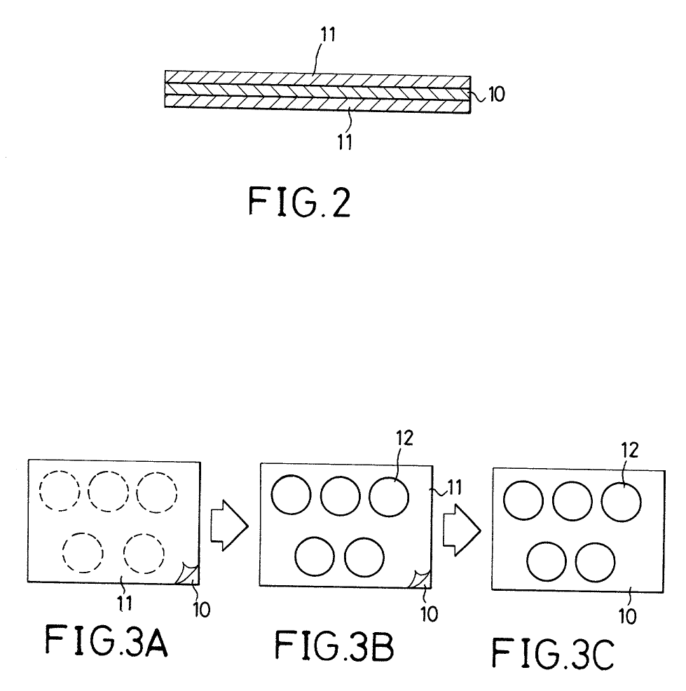

With reference to FIGS. 1 to FIG. 3, the invention relates to a method of making a planar inductance, which includes the steps of:

a process of producing a core (10) with high magnetic flux, which includes the steps of adding dry foils (11) with pattern on opposite sides of the core (10) and transforming the pattern of the dry foil (11) by any appropriate means known in the art on the surface of the core (10); wherein the core is made by a metal selected from the group consisting of iron, magnesium, cobalt and manganese.

After the pattern are formed on the core (10), the dry foil (11) is removed and first holes (12) are defined through the core (10).

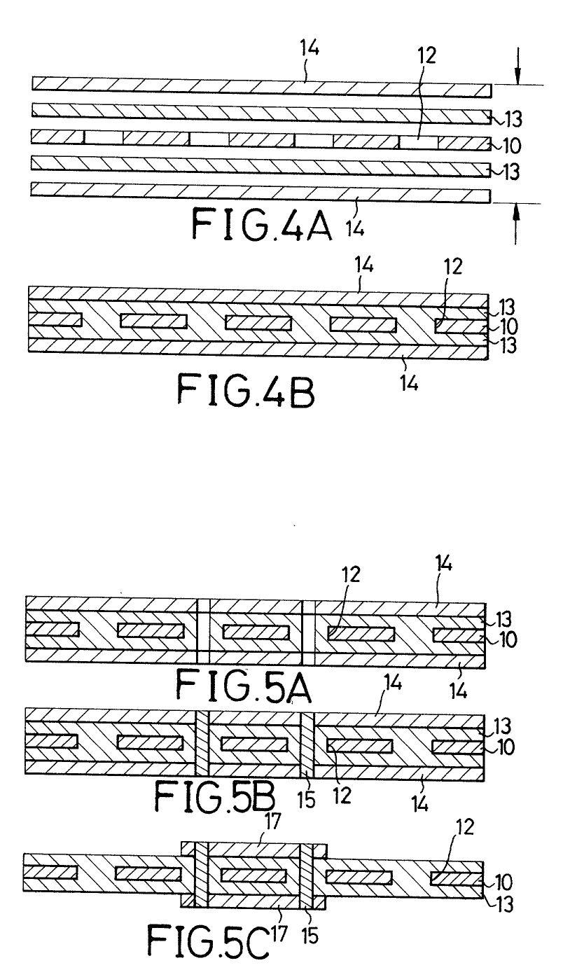

a process of sequentially pressing insulator (13) made of epoxy resin and copper foil (14) on the core (10) so as to press part of the insulator (13) into the first holes (12) defined through the opposite sides of the core (10), as shown in FIGS. 4A and 4B;

a process of metalizing second holes defined to correspond to the first holes (12) for generating electrical connection between the copper foils (14) on the opposite sides on the core; wherein metalizing means to plate copper (15) in the second hole, as shown in FIG. SB, such that the copper foil (14) on opposite sides of the insulator (13) are electrically connected with each other by means of the plated copper (15) in the second hole; and

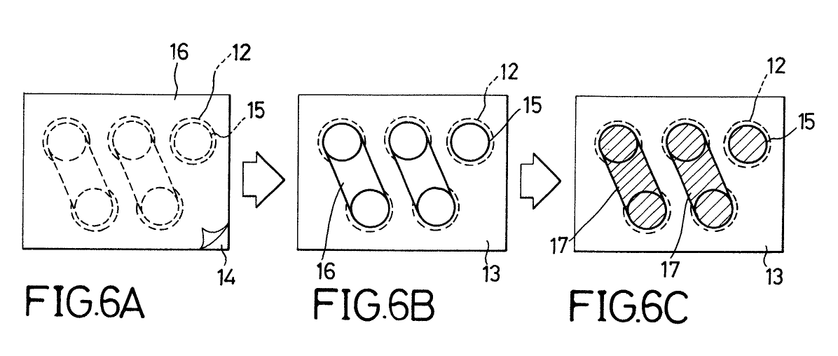

a process of forming copper traces on dry foils (16) added on top of the copper foils (14), as shown in FIGS. 6A˜6C, which uses a photographic technique to transform patterns on the dry foils (16) onto the copper foil (14) and then excess copper is removed from the dry foil (16) so as to form copper traces (17) on the insulator (13).

After the above processes are finished, the copper traces (17) on one side of the insulator (13) is electrically connected with the copper traces (17) on the other side of the insulator (13), such that an inductance is made.

The process for making an inductance of the invention can also be used to make a transformer, which includes the process of:

a process of producing a core (10) with high magnetic flux, which includes the steps of adding dry foils (11) with pattern on opposite sides of the core (10) and transforming the pattern of the dry foil (11) by any appropriate means known in the art on the surface of the core (10); wherein the core is made by a metal selected from the group consisting of iron, magnesium, cobalt and manganese.

After the pattern are formed on the core (10), the dry foil (11) is removed and first holes (12) are defined through the core (10).

a process of sequentially pressing insulator (13) made of epoxy resin and copper foil (14) on the core (10) so as to press part of the insulator (13) into the first holes (12) defined through the opposite sides of the core (10), as shown in FIGS. 4A and 4B;

a process of metalizing second holes defined to correspond to the first holes (12) for generating electrical connection between the copper foils (14) on the opposite sides on the core; wherein metalizing means to plate copper (15) in the second hole, as shown in FIG. 5B, such that the copper foil (14) on opposite sides of the insulator (13) are electrically connected with each other by means of the plated copper (15) in the second hole; and

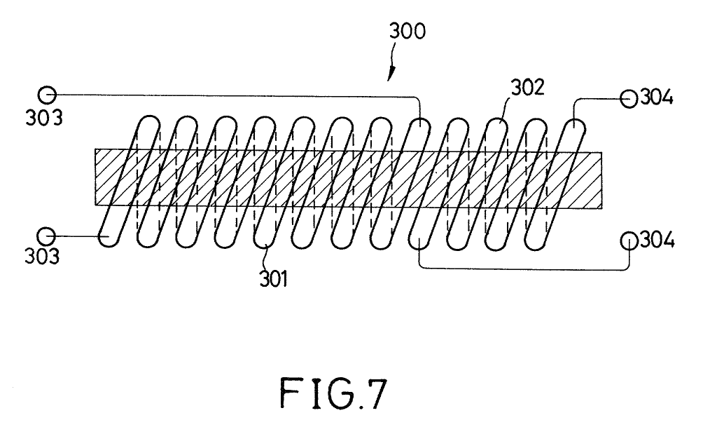

a process of forming copper traces on dry foils (16) added on top of the copper foils (14), as shown in FIGS. 6A˜6C, which uses a photographic technique to transform patterns on the dry foils (16) onto the copper foil (14) and then excess copper is removed from the dry foil (16) so as to form copper traces (17) on the insulator (13). After which, the copper traces (17) on the inductance are broken to form a first runner (301) and a second runner (302) and then distal ends of the first runner (301) and the second runner (302) extend out for further electrical connection. Thus, a transformer is made, as shown in FIG. 7.

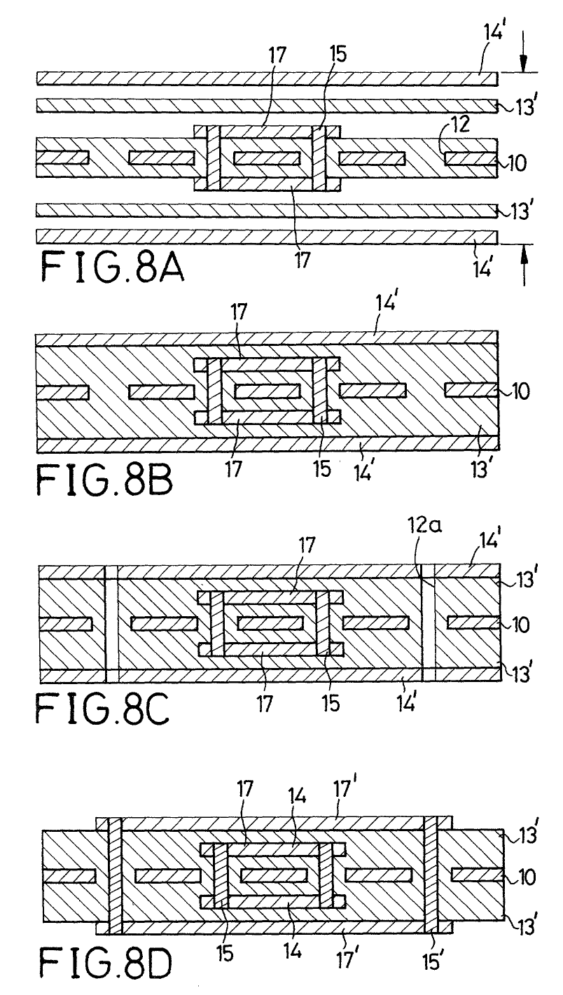

Another preferred method for producing a transformer is shown in FIG. 8, which is an extension of the method of producing a planar inductance. The method comprises the steps of:

a process of producing a core with high magnetic flux;

a process of sequentially pressing insulator made of epoxy resin and copper foil on the core so as to press part of the insulator into the first holes defined through the opposite sides of the core;

a process of metalizing second holes defined to correspond to the first holes for generating electrical connection between the copper foils on the opposite sides on the core; and

a process of forming copper traces on dry foils added on top of the copper foils.

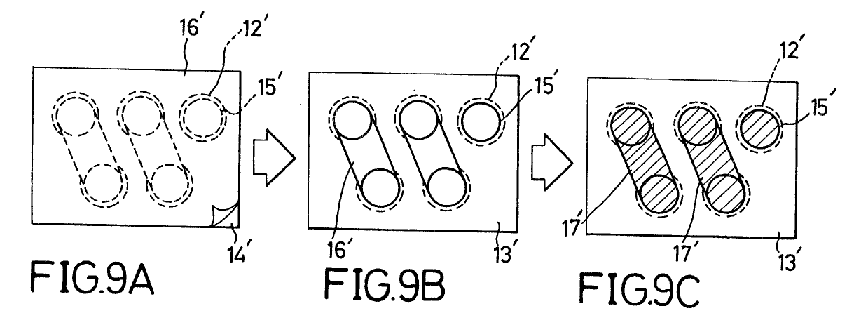

Basically, the process of this preferred method is the same as the process described before FIG. SB, the difference lies on the repetition of the process of pressing an insulator (13′) and a copper foil (14′) on the above finished product, as shown in FIG. 8A and FIG. 8B. When the pressing process is finished, metalizing third holes defined through the copper foil (14′) and the finished inductance so as to establish electrical connection between the added copper foil (14′) by plated copper (15′) in the third holes, as shown in FIG. 8C and FIG. 8D. Thereafter, the process of forming copper traces is implemented again so as to form copper traces (17′) on the insulator (13′). The detailed process of forming copper traces (17′) is shown in FIG. 9A˜FIG. 9C. A dry foil (16′) with pattern is added to the surface of the copper foil (14′). Then, a photographic technique is used to transform the pattern of the dry foil (16′) onto the surface of the copper foil (14′). Thereafter, the dry foil (16′) is removed from the surface of the copper foil (14′) and an etching method is used to remove the excess copper foil (14′) to leave the pattern on the insulator (13′), which become copper traces (17′).

Thus, the copper traces (17) form a first runner and the copper traces (17′) electrically connected with the copper traces (17) form a second runner of a transformer.

Furthermore, if the eddy current and the heat dissipation problem of the transformer made are taking into concern, the core (10) can be divided into several layers and an insulator (13) is added between two adjacent layers of the divided core (10), such that not only the eddy current is reduced, but also the heat dissipation effect is increased.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A method for making a transformer comprising the steps of:
a process of producing a core with high magnetic flux;
a process of sequentially pressing a first insulator and a first copper foil on the core so as to press part of the insulator into first holes defined through the opposite sides of the core;
a process of metalizing second holes defined to correspond to the first holes for generating electrical connection between the first copper foils on opposite sides on the core;
a process of forming copper traces on dry foils added on top of the first copper foils;
a process of sequentially pressing a second insulator and a second copper foil on the first copper foil so as to press part of the second insulator into the third holes defined through the opposite sides of the first copper foil;
a process of metalizing fourth holes defined to correspond to the third holes for generating electrical connection between the second copper foils on the opposite sides on the first copper foil; and
a process of forming copper traces on dry foils added on top of the second copper foils.

2. The method as claimed in claim 1, wherein the second insulator is made of epoxy resin.

3. The method as claimed in claim 1, wherein the second insulator will be pressed into the third holes in the pressing process.

4. The method as claimed in claim 2, wherein the metalizing process is plating.

5. The method as claimed in claim 2, wherein the copper trace forming step is done by photography and etching so as to first print a predetermined trace on the second copper foil and then excess second copper foil outside the trace is etched in order to form copper traces on the second insulator.

6. The method as claimed in claim 1, wherein the core forming process further comprises the steps of:
adding dry foils on opposite sides of the core; and
etching the dry foils to form traces on the surface of the core

7. The method as claimed in claim 1, wherein the core is made from a metal selected from the group consisting of iron, magnesium, cobalt and manganese.
